(19) United States
(12) Patent Application Publication
(10) Pub. No.: US 2020/0412303 A1
(43) Pub. Date: Dec. 31, 2020

(54) FREQUENCY COMPENSATION OF AMPLIFIER

(71) Applicant: Avago Technologies International Sales Pte. Limited, Singapore (SG)

(72) Inventor: Santosh Astgimath, Edinburgh (GB)

(21) Appl. No.: 16/452,797

(22) Filed: Jun. 26, 2019

(51) Int. Cl. H03F 1/08; H03F 3/45

(52) U.S. Cl. CPC H03F 1/086; H03F 3/45094

(57) ABSTRACT

Disclosed herein are related to an apparatus and a method for implementing an amplifier with an improved stability for feedback operation. In one aspect, the apparatus includes a cascode circuit including a first transistor and a second transistor coupled to each other in series. The cascode circuit may generate a first amplified signal by amplifying an input signal. In one aspect, the apparatus includes an amplifier circuit coupled to an output of the cascode circuit. The amplifier circuit may generate a second amplified signal by amplifying the first amplified signal. In one aspect, the apparatus includes an output circuit coupled to an output of the amplifier circuit. The output circuit may generate an output signal by amplifying the second amplified signal. In one aspect, the apparatus includes a first capacitor disposed across the second transistor, and a second capacitor coupled between the output circuit and the cascode circuit.

### FIELD OF THE DISCLOSURE

This disclosure generally relates to systems and methods for implementing an amplifier with an improved stability for feedback operation, including but not limited to a frequency compensation of a two stage or a higher stage amplifier.

### BACKGROUND OF THE DISCLOSURE

Negative feedback amplifiers are prevalent in electronic devices. For example, a negative feedback amplifier is implemented to track an input signal or control an output signal according to the input signal. A negative feedback amplifier with a higher unity gain bandwidth (UGB) may track the input signal or control the output signal according to the input signal with a higher frequency.

In general, an amplifier design is subject to various trade-offs. For example, higher open loop gain may increase a UGB, but may shift a location of a pole to decrease a phase margin. An amplifier with an insufficient phase margin (e.g., less than 50 degrees) may cause the amplifier in a negative feedback configuration to be unstable. Conversely, reducing the opening loop gain may help improve the stability, but may reduce the UGB. For another example, increasing a dynamic range or a load current supplied by an amplifier changes a transconductance or a gain of the amplifier that may alter the unity bandwidth or the phase margin.

### SUMMARY

Various embodiments disclosed herein are related to an apparatus for a negative feedback. In some embodiments, the apparatus includes an input sensing circuit to generate an input signal. In some embodiments, the apparatus includes a cascode circuit coupled to the input sensing circuit. In some embodiments, the cascode circuit includes a first transistor and a second transistor coupled to each other in series. In some embodiments, the cascode circuit is configured to generate a first amplified signal by amplifying the input signal from the input sensing circuit. In some embodiments, the apparatus includes an amplifier circuit coupled to an output of the cascode circuit. In some embodiments, the amplifier circuit is configured to generate a second amplified signal by amplifying the first amplified signal. In some embodiments, the apparatus includes an output circuit coupled to an output of the amplifier circuit. In some embodiments, the output circuit is configured to generate an output signal by amplifying the second amplified signal. In some embodiments, the apparatus includes a first capacitor disposed across the second transistor, and a second capacitor coupled between the output circuit and the cascode circuit.

In some embodiments, the first capacitor is coupled between a first electrode of the second transistor and a second electrode of the second transistor. In some embodiments, the second capacitor is coupled between an output of the output circuit and the second electrode of the second transistor. In some embodiments, the second electrode of the second transistor is the output of the cascode circuit. In some embodiments, the apparatus further includes a third capacitor coupled between the output of the output circuit and a third electrode of the second transistor. In some embodiments, the input sensing circuit is directly coupled to the third electrode of the second transistor.

In some embodiments, the cascode circuit further includes a pair of buffer transistors, a third transistor, and a fourth transistor. In some embodiments, the first transistor, the second transistor, the pair of buffer transistors, the third transistor, and the fourth transistor are coupled to each other in series.

In some embodiments, the first transistor and the second transistor are N-type transistors, and the third transistor and the fourth transistor are P-type transistors. In some embodiments, the pair of buffer transistors include an N-type transistor and a P-type transistor coupled to each other in parallel.

In some embodiments, the apparatus further includes a fourth capacitor coupled between a first electrode and a second electrode of the fourth transistor. In some embodiments, the apparatus further includes a fifth capacitor coupled between the second electrode of the fourth transistor and the output of the output circuit. In some embodiments, the apparatus further includes a sixth capacitor coupled between a third electrode of the fourth transistor and the output of the output circuit. In some embodiments, the apparatus further includes another amplifier circuit coupled between the second electrode of the fourth transistor and another input of the output circuit. In some embodiments, the input sensing circuit and the cascode circuit form a folded cascode amplifier.

In some embodiments, the apparatus further includes a switch coupled to the first capacitor in series across the second transistor. In some embodiments, the apparatus further includes a frequency compensation controller coupled to the output circuit, where the frequency compensation controller is configured to sense load current through the output circuit and enable or disable the switch according to the load current. In some embodiments, the amplifier circuit is configured to adjust an amplification gain for amplifying the first amplified signal according to a voltage at the output of the output circuit. In some embodiments, the amplifier circuit includes an input transistor including a gate electrode coupled to the output of the cascode circuit. In some embodiments, the amplifier circuit includes a diode connected transistor including a source electrode coupled to a source electrode of the input transistor, and a drain electrode coupled to a gate electrode of the diode connected transistor. In some embodiments, the drain electrode of the diode connected transistor is coupled to an input of the output circuit. In some embodiments, the apparatus includes a resistor coupled between the source electrode of the diode connected transistor and the drain electrode of the diode connected transistor.

Various embodiments disclosed herein are related to an apparatus for a negative feedback. In some embodiments, the apparatus includes a cascode circuit including a first transistor and a second transistor coupled to each other in series. In some embodiments, the cascode circuit is configured to generate a first amplified signal by amplifying an input signal. In some embodiments, the apparatus includes an amplifier circuit coupled to an output of the cascode circuit. In some embodiments, the amplifier circuit is configured to generate a second amplified signal by amplifying the first amplified signal. In some embodiments, the apparatus includes an output circuit coupled to an output of the amplifier circuit. In some embodiments, the output circuit is configured to generate an output signal by amplifying the second amplified signal. In some embodiments, the apparatus includes a first capacitor and a switch coupled to each other in series between a gate electrode of the second transistor and a drain electrode of the second transistor. In some embodiments, the apparatus includes a second capacitor coupled between an output of the output circuit and the drain electrode of the second transistor.

In some embodiments, the apparatus includes a frequency compensation controller coupled to the output circuit, where the frequency compensation controller is configured to sense load current through the output circuit and enable or disable the switch according to the load current. In some embodiments, the apparatus includes a third capacitor coupled between the output of the output circuit and a source electrode of the second transistor. In some embodiments, the amplifier circuit is configured to adjust an amplification gain for amplifying the first amplified signal according to a voltage at the output of the output circuit.

Various embodiments disclosed herein are related to a method of controlling a negative feedback system. In some embodiments, the method includes amplifying, by a cascode circuit including a first transistor and a second transistor coupled to each other in series, an input signal to generate a first amplified signal. In some embodiments, the method includes amplifying, by an amplifier circuit coupled to an output of the cascode circuit, the first amplified signal to generate a second amplified signal. In some embodiments, the method includes amplifying, by an output circuit coupled to an output of the amplifier circuit, the second amplified signal to generate an output signal. In some embodiments, the method includes adjusting, by the amplifier circuit, an amplification gain for amplifying the first amplified signal according to a load current through the output circuit.

In some embodiments, the method includes sensing, by a frequency compensation controller coupled to the output circuit, the load current through the output circuit. In some embodiments, the method includes enabling or disabling, by the frequency compensation controller, a switch coupled to the first capacitor in series across the second transistor according to the load current.

### BRIEF DESCRIPTION OF THE DRAWINGS

Various objects, aspects, features, and advantages of the disclosure will become more apparent and better understood by referring to the detailed description taken in conjunction with the accompanying drawings, in which like reference characters identify corresponding elements throughout. In the drawings, like reference numbers generally indicate identical, functionally similar, and/or structurally similar elements.

FIG. 1 is a diagram depicting an example amplifier with a feedback configuration.

FIG. 2 is a diagram depicting an example first stage amplifier.

FIG. 3 is a diagram depicting an example second stage amplifier.

FIG. 4 is a diagram depicting an example arrangement with a connection between the first stage amplifier and the second stage amplifier.

FIG. 5 is a diagram depicting an example arrangement with a connection between the first stage amplifier and the second stage amplifier with capacitors disposed across cascode transistors to improve stability.

FIG. 6 is a diagram depicting an example arrangement with a connection between the first stage amplifier and the second stage amplifier with an adjustable frequency compensation.

FIG. 7 is a diagram depicting an example arrangement with an amplifier between the first stage amplifier and the second stage amplifier.

FIG. 8 is a flow chart depicting an example operation of adjusting an amplifier gain for improving stability.

FIG. 9A is a block diagram depicting an embodiment of a network environment including one or more network devices in communication with one or more devices or stations.

FIGS. 9B and 9C are block diagrams depicting embodiments of computing devices useful in connection with the methods and systems described herein.

The details of various embodiments of the methods and systems are set forth in the accompanying drawings and the description below.

### DETAILED DESCRIPTION

For purposes of reading the description of the various embodiments below, the following descriptions of the sections of the specification and their respective contents may be helpful:
Section A describes embodiments of an amplifier with frequency compensation for feedback operation; and
Section B describes a network environment and computing environment which may be useful for practicing embodiments described herein.
   A. Amplifier with Frequency Compensation

Disclosed herein are related to various aspects of an apparatus and a method for implementing a negative feedback system with an improved stability and bandwidth. In some embodiments, the apparatus includes a cascode circuit including a first transistor and a second transistor coupled to each other in series. In some embodiments, the cascode circuit generates a first amplified signal by amplifying an input signal. In some embodiments, the apparatus includes an amplifier circuit coupled to an output of the cascode circuit. In some embodiments, the amplifier circuit generates a second amplified signal by amplifying the first amplified signal. In some embodiments, the apparatus includes an output circuit coupled to an output of the amplifier circuit. In some embodiments, the output circuit generates an output signal by amplifying the second amplified signal. In some embodiments, the apparatus includes a first capacitor disposed across the second transistor, and a second capacitor coupled between the output circuit and the cascode circuit.

Advantageously, the disclosed system and method allow frequency compensation of a two stage amplifier or a higher stage amplifier such that a high UGB and an improved stability can be achieved. In particular, a capacitor across a cascode transistor of the cascode circuit allows a high gain at a first frequency (e.g., near DC) and reduces gain at a second frequency higher than the first frequency, in some embodiments. In some embodiments, a cascode transistor is a transistor that is located away from an AC ground (e.g., supply voltage rail or ground voltage rail) from two or more transistors connected to each other in series in a cascode structure. Moreover, the capacitor may be adaptively coupled or decoupled across the transistor, according to a load current through the output circuit. Hence, a dynamic range of the amplifier can be improved by enabling or disabling frequency compensation or suppression of gain by the capacitor according to the load current without sacrificing the stability of the negative feedback system. Accordingly, the disclosed amplifier can be implemented in a negative configuration with faster tracking or better control.

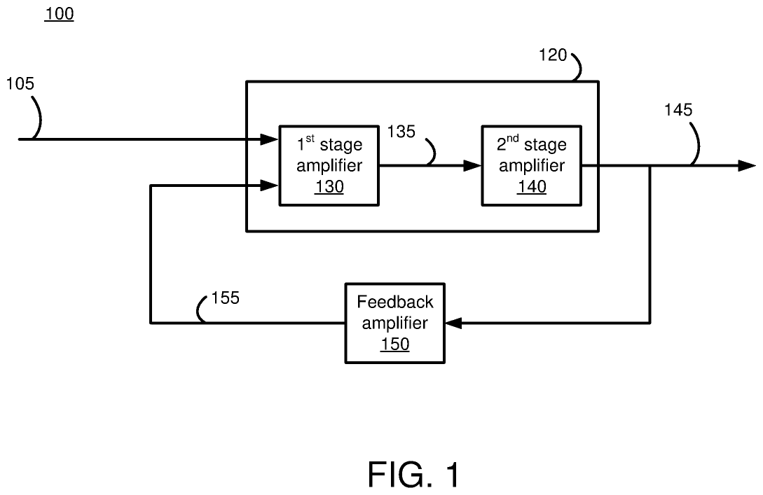

Referring to FIG. 1, illustrated is a diagram depicting an example apparatus or system 100 with an amplifier in a negative feedback configuration, according to some embodiments. In some embodiments, the system 100 includes a high-gain amplifier 120, and a feedback amplifier 150. In some embodiments, these components operate together to receive an input signal 105, and generate an output signal 145 that tracks the input signal 105 or is controlled according to the input signal 105. For example, a voltage or current of the output signal 145 in voltage or current tracks or follows a voltage or current of the input signal 105. In one aspect, the high-gain amplifier 120 includes at least a first stage amplifier 130 and a second stage amplifier 140 with frequency compensation as disclosed herein, such that the output signal 145 can track the input signal 105 or can be controlled according to the input signal 105. In some embodiments, these components are circuitry implemented on a single integrated circuit (e.g., application specific integrated circuit) or on multiple integrated circuits. In some embodiments, the system 100 includes more, fewer, or different components than shown in FIG. 1. For example, the feedback amplifier 150 may be omitted or bypassed.

In some embodiments, the high-gain amplifier 120 receives the input signal 105 and a feedback signal 155, and amplifies a difference between the input signal 105 and the feedback signal 155 to generate the output signal 145. In one configuration, the high-gain amplifier 120 includes a first input port to receive the input signal 105, a second input port coupled to an output port of the feedback amplifier 150 to receive the feedback signal 155, and an output port to provide the output signal 145. The output port of the high-gain amplifier 120 may be coupled to a load (or another device), and the high-gain amplifier 120 may drive, provide, or supply current or voltage to the load through the output port. For example, the first stage amplifier 130 amplifies a difference between the input signal 105 and the feedback signal 155, and amplifies the difference to generate an intermediate signal 135, and the second stage amplifier 140 amplifies the intermediate signal 135 to generate the output signal 145. In one aspect, the second stage amplifier 140 may be referred to as “an output circuit” that provides the output voltage, output current or both. The intermediate signal 135 and the output signal 145 may be in a single ended representation or in a differential representation.

In some embodiments, the feedback amplifier 150 receives the output signal 145 from the high-gain amplifier 120, and generates the feedback signal 155 according to the output signal 145. In one configuration, the feedback amplifier 150 includes an input port coupled to the output port of the high-gain amplifier 120 to receive the output signal 145 and the output port coupled to the second input port of the high-gain amplifier 120 to provide the feedback signal 155. In some embodiments, the feedback amplifier 150 receives the output signal 145 and amplifies the output signal 145 by a feedback factor (e.g., less than ‘1’, equal to ‘1’, or larger than ‘1’) to generate the feedback signal 155. In one aspect, through the negative feedback operation of the high-gain amplifier 120 and the feedback amplifier 150, the output signal 145 can track the input signal 105 or can be controlled according to the input signal 105, if a frequency of the input signal 105 is less than a UGB of the system 100. In one aspect, a high UGB (e.g., over 100 MHz or 1 GHz) of the system 100 with improved stability can be achieved through the disclosed feedback compensation as disclosed below.

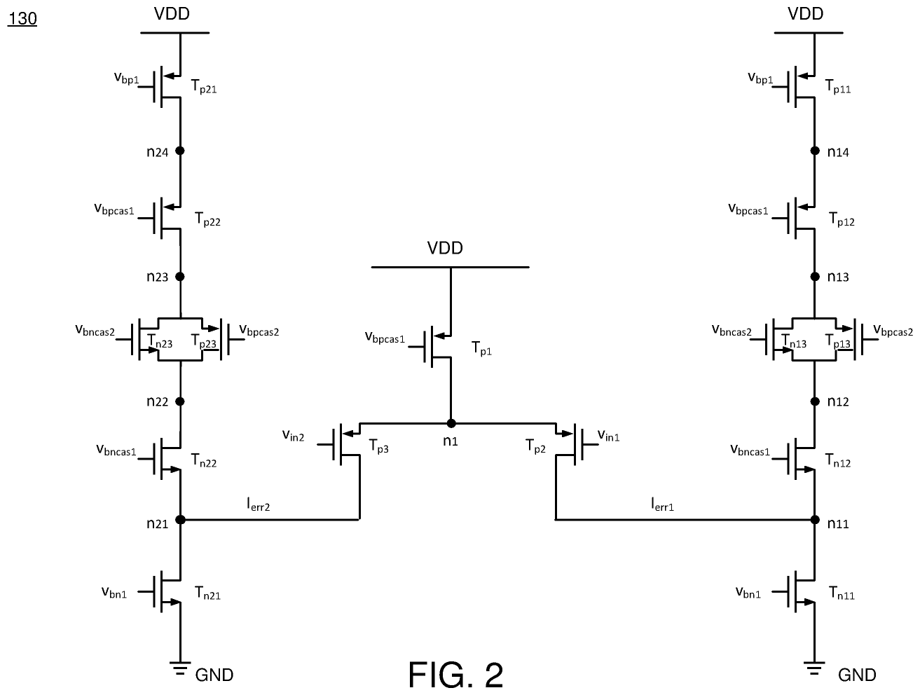

Referring to FIG. 2, illustrated is a diagram depicting an example first stage amplifier 130 of FIG. 1, in some embodiments. In some embodiments, the first stage amplifier 130 includes transistors Tₚ₁, Tₚ₂, Tₚ₃, Tₚ₁₁, Tₚ₁₂, Tₚ₁₃, Tₚ₂₁, Tₚ₂₂, Tₚ₂₃, Tₙ₁₁, Tₙ₁₂, Tₙ₁₃, Tₙ₂₁, Tₙ₂₂, Tₙ₂₃ formed together in a folded cascode amplifier structure. In some embodiments, the transistors Tₚ₁, Tₚ₂, Tₚ₃, Tₚ₁₁, Tₚ₁₂, Tₚ₁₃, Tₚ₂₁, Tₚ₂₂, Tₚ₂₃ are P-type transistors (e.g., PMOS transistors), and transistors Tₙ₁₁, Tₙ₁₂, Tₙ₁₃, Tₙ₂₁, Tₙ₂₂, Tₙ₂₃ are N-type transistors (e.g., NMOS transistors). In this configuration, these components may operate together to receive input voltages Vᵢₙ₁, Vᵢₙ₂, and amplify the difference between the input voltages Vᵢₙ₁, Vᵢₙ₂ to generate output voltages indicating the amplified voltage difference at nodes n₁₂, n₁₃, n₂₂, n₂₃. In one aspect, one of the input voltages Vᵢₙ₁, Vᵢₙ₂ corresponds to the input signal 105 of FIG. 1, the other of the input voltages Vᵢₙ₁, Vᵢₙ₂ corresponds to the feedback signal 155 of FIG. 1, and output voltages at the nodes n₁₂, n₁₃, n₂₂, n₂₃ correspond to the intermediate signal 135 of FIG. 1. In some embodiments, the first stage amplifier 130 includes more, fewer, or different components than shown in FIG. 2. In some embodiments, the first stage amplifier 130 includes transistors to form an amplifier with a different structure (e.g., telescopic amplifier structure) than that shown in FIG. 2.

The transistors Tₚ₁, Tₚ₂, Tₚ₃ operate together to sense a voltage difference between the input voltages Vᵢₙ₁, Vᵢₙ₂, in one or more embodiments. In one configuration, a source electrode of the transistor Tₚ₁ is coupled to a supply voltage rail to receive a first reference voltage (e.g., VDD or 1.2V), and a gate electrode of the transistor Tₚ₁ is coupled to a bias device (not shown for simplicity) to receive a bias voltage V_{bpcas1}. In one configuration, a drain electrode of the transistor Tₚ₁ is coupled to a source electrode of the transistor Tₚ₂ and a source electrode of the transistor Tₚ₃. In one configuration, a gate electrode of the transistor Tₚ₂ is configured to receive the input voltage Vᵢₙ₁, and a drain electrode of the transistor Tₚ₂ is directly or indirectly coupled to a node n₁₁. In one configuration, a gate electrode of the transistor Tₚ₃ is configured to receive the input voltage Vᵢₙ₂, and a drain electrode of the transistor Tₚ₃ is directly or indirectly coupled to a node n₂₁. In this configuration, the transistor Tₚ₁ operates as a current source that supplies current to the source electrodes of the transistors Tₚ₂, Tₚ₃, according to the bias voltage V_{bpcas1}. In this configuration, the transistors Tₚ₂, Tₚ₃ operate as a differential pair input sensing circuit that senses a difference between the input voltages Vᵢₙ₁, Vᵢₙ₂, and steers current from the transistor Tₚ₁ according to the sensed voltage difference to provide sensed current Iₑᵣᵣ₁ and Iₑᵣᵣ₂. For example, in response to the input voltage Vᵢₙ₁ being higher than the input voltage Vᵢₙ₂, more current is injected to the transistor Tₚ₃ than the transistor Tₚ₂. For another example, in response to the input voltage Vᵢₙ₂ being higher than the input voltage Vᵢₙ₁, more current is injected to the transistor Tₚ₂ than the transistor Tₚ₃.

In some embodiments, the transistors Tₙ₁₁, Tₙ₁₂, Tₙ₁₃, Tₙ₂₁, Tₙ₂₂, Tₙ₂₃, Tₚ₁₁, Tₚ₁₂, Tₚ₁₃, Tₚ₂₁, Tₚ₂₂, Tₚ₂₃ operate together to receive the sensed currents Iₑᵣᵣ₁ and Iₑᵣᵣ₂, and convert the sensed currents Iₑᵣᵣ₁ and Iₑᵣᵣ₂ into voltages at the nodes n₁₂, n₁₃, n₂₂, n₂₃. In one aspect, the transistors Tₙ₁₁, Tₙ₁₂, Tₚ₁₁, Tₚ₁₂ are coupled to each other in series and may operate together as a half circuit to receive the sensed current Iₑᵣᵣ₁ and convert the sensed current Iₑᵣᵣ₁ into corresponding voltages at the nodes n₁₂, n₁₃. The transistors Tₙ₁₃ and Tₚ₁₃ may operate together as a buffer between the nodes n₁₂, n₁₃. Similarly, the transistors Tₙ₂₁, Tₙ₂₂, Tₚ₂₁, Tₚ₂₂ are coupled to each other in series and may operate together as the other half circuit to receive the sensed current Iₑᵣᵣ₂ and convert the sensed current Iₑᵣᵣ₂ into corresponding voltages at the nodes n₂₂, n₂₃. The transistors Tₙ₂₃ and Tₚ₂₃ may operate together as buffer between the nodes n₂₂, n₂₃.

In one configuration, a source electrode of the transistor Tₙ₁₁ is coupled to a ground voltage rail to receive a second reference voltage (e.g., GND or 0V), a gate electrode of the transistor Tₙ₁₁ is coupled to a bias device (not shown for simplicity) to receive a bias voltage V_{bn1}, and a drain electrode of the transistor Tₙ₁₁ is coupled to a node n₁₁. In one configuration, a source electrode of the transistor Tₙ₁₂ is coupled to the node n₁₁, a gate electrode of the transistor Tₙ₁₂ is coupled to a bias device (not shown for simplicity) to receive a bias voltage V_{bncas1}, and a drain electrode of the transistor Tₙ₁₂ is coupled to the node n₁₂. In this configuration, the sensed current Iₑᵣᵣ₁ is injected into the node n₁₁, and the sensed current Iₑᵣᵣ₁ is converted into a voltage by the transistors Tₙ₁₁, Tₙ₁₂ at the node n₁₂. In one aspect, the transistors Tₙ₁₁, Tₙ₁₂ are connected to each other in series to form a cascode structure or a cascode circuit with the transistor Tₙ₁₂ being a cascode transistor to provide a high output impedance at the node n₁₂ to render a high voltage gain between a voltage at the node n₁₂ and the input voltage Vᵢₙ₁.

In one aspect, the transistors Tₙ₁₃, Tₚ₁₃ are coupled to each other in parallel between the nodes n₁₂, n₁₃. In one configuration, a source electrode of the transistor Tₙ₁₃ is coupled to the node n₁₂, a gate electrode of the transistor Tₙ₁₃ is coupled to a bias device (not shown for simplicity) to receive a bias voltage V_{bncas2}, and a drain electrode of the transistor Tₙ₁₃ is coupled to the node n₁₃. In one configuration, a source electrode of the transistor Tₚ₁₃ is coupled to the node n₁₃, a gate electrode of the transistor Tₚ₁₃ is coupled to a bias device (not shown for simplicity) to receive a bias voltage V_{bpcas2}, and a drain electrode of the transistor Tₚ₁₃ is coupled to the node n₁₂. In this configuration, the transistors Tₙ₁₃, Tₚ₁₃ operate as a pair of buffer transistors between the nodes n₁₂, n₁₃ to separate the voltages at the nodes n₁₂, n₁₃.

In one configuration, a source electrode of the transistor Tₚ₁₁ is coupled to the supply voltage rail to receive the first reference voltage (e.g., VDD or 1.2V), a gate electrode of the transistor Tₚ₁₁ is coupled to a bias device (not shown for simplicity) to receive a bias voltage V_{bp1}, and a drain electrode of the transistor Tₚ₁₁ is coupled to a node n₁₄. In one configuration, a source electrode of the transistor Tₚ₁₂ is coupled to the node n₁₄, a gate electrode of the transistor Tₚ₁₂ is coupled to a bias device (not shown for simplicity) to receive a bias voltage V_{bpcas1}, and a drain electrode of the transistor Tₚ₁₂ is coupled to the node n₁₃. In this configuration, current flowing through the transistor Tₙ₁₂ according to the sensed current Iₑᵣᵣ₁ at the node n₁₁ may flow through the transistors Tₚ₁₁, Tₚ₁₂ or cause a corresponding amount of current to flow through the transistors Tₚ₁₁, Tₚ₁₂. In one aspect, the transistors Tₚ₁₁, Tₚ₁₂ are connected to each other in series to form a cascode structure or a cascode circuit with the transistor Tₚ₁₂ being a cascode transistor to provide a high output impedance at the node n₁₃ to render a high voltage gain between a voltage at the node n₁₃ and the input voltage Vᵢₙ₁.

In some embodiments, the transistors Tₙ₂₁, Tₙ₂₂, Tₙ₂₃, Tₚ₂₁, Tₚ₂₂, Tₚ₂₃ are configured and operate in a similar manner as the transistors Tₙ₁₁, Tₙ₁₂, Tₙ₂₃, Tₚ₁₁, Tₚ₁₂, Tₚ₁₃, such that the transistors Tₙ₁₁, Tₙ₁₂, Tₙ₁₃, Tₚ₁₁, Tₚ₁₂, Tₚ₁₃ operate as the half circuit, and the transistors Tₙ₂₁, Tₙ₂₂, Tₙ₂₃, Tₚ₂₁, Tₚ₂₂, Tₚ₂₃ operate as the other half circuit. For example, the sensed current Iₑᵣᵣ₂ can be injected at the node n₂₁ and converted into voltages at the nodes n₂₂, n₂₃ by the transistors Tₙ₂₁, Tₙ₂₂, Tₙ₂₃, Tₚ₂₁, Tₚ₂₂, Tₚ₂₃. Thus, duplicated description thereof is omitted herein for the sake of brevity.

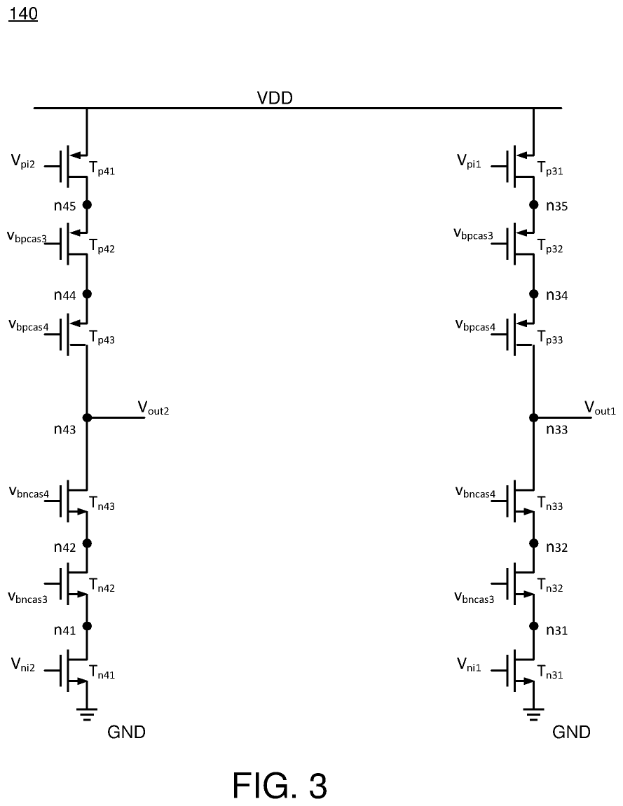

Referring to FIG. 3, illustrated is a diagram depicting an example second stage amplifier 140. In some embodiments, the second stage amplifier 140 includes transistors Tₚ₃₁, Tₚ₃₂, Tₚ₃₃, Tₚ₄₁, Tₚ₄₂, Tₚ₄₃, Tₙ₃₁, Tₙ₃₂, Tₙ₃₃, Tₙ₄₁, Tₙ₄₂, Tₙ₄₃ formed together in cascode structures. In some embodiments, the transistors Tₚ₃₁, Tₚ₃₂, Tₚ₃₃, Tₚ₄₁, Tₚ₄₂, Tₚ₄₃ are P-type transistors (e.g., PMOS transistors), and Tₙ₃₁, Tₙ₃₂, Tₙ₃₃, Tₙ₄₁, Tₙ₄₂, Tₙ₄₃ are N-type transistors (e.g., NMOS transistors). In this configuration, these components may operate together to receive voltages Vₚᵢ₁, Vₚᵢ₂, and amplify the difference between the voltages Vₚᵢ₁, Vₚᵢ₂ to generate output voltages Vₒᵤₜ₁, Vₒᵤₜ₂, indicating the amplified voltage difference at nodes n₃₃, n₄₃. Similarly, these components may operate together to receive voltages Vₙᵢ₁, Vₙᵢ₂, and amplify the difference between the voltages Vₙᵢ₁, Vₙᵢ₂ to generate output voltages Vₒᵤₜ₁, Vₒᵤₜ₂ indicating the amplified voltage difference at nodes n₃₃, n₄₃. The voltages Vₚᵢ₁, Vₚᵢ₂ may be or correspond to differential voltages at the nodes n₁₃, n₂₃ of FIG. 2, respectively. Similarly, the voltages Vₙᵢ₁, Vₙᵢ₂ may be or correspond to differential voltages at the nodes n₁₂, n₂₂ of FIG. 2, respectively. The voltage Vₙᵢ₁ may be a counterpart of (or have an opposite phase with respect to) the voltage Vₚᵢ₁, and the voltage Vₙᵢ₂ may be a counterpart of (or have an opposite phase with respect to) the voltage Vₚᵢ₂. In some embodiments, the second stage amplifier 140 includes more, or fewer, or different components than shown in FIG. 3. In some embodiments, the second stage amplifier 140 includes transistors to form an amplifier with a different structure than shown in FIG. 3.

In some embodiments, the transistors Tₙ₃₁, Tₙ₃₂, Tₙ₃₃, Tₙ₄₁, Tₙ₄₂, Tₙ₄₃, Tₚ₃₁, Tₚ₃₂, Tₚ₃₃, Tₚ₄₁, Tₚ₄₂, Tₚ₄₃ operate together to receive the voltages Vₚᵢ₁, Vₚᵢ₂, Vₙᵢ₁, Vₙᵢ₂, and amplify the received voltages to generate output voltages Vₒᵤₜ₁, Vₒᵤₜ₂ at the nodes n₃₃, n₄₃. In one aspect, the transistors Tₙ₃₁, Tₙ₃₂, Tₙ₃₃, Tₚ₃₁, Tₚ₃₂, Tₚ₃₃ are coupled to each other in series and may operate together as a half circuit to receive the voltages Vₙᵢ₁, Vₚᵢ₁, and amplify the voltages Vₙᵢ₁, Vₚᵢ₁ to generate the output voltage Vₒᵤₜ₁ at the node n₃₃. Similarly, the transistors Tₙ₄₁, Tₙ₄₂, Tₙ₄₃, Tₚ₄₁, Tₚ₄₂, Tₚ₄₃ are coupled to each other in series and may operate together as the other half circuit to receive the voltages Vₙᵢ₂, Vₚᵢ₂, and amplify the voltages Vₙᵢ₂, Vₚᵢ₂ to generate the output voltage Vₒᵤₜ₂ at the node n₄₃.

In one configuration, a source electrode of the transistor Tₙ₃₁ is coupled to the ground voltage rail to receive the second reference voltage (e.g., GND or 0V), a gate electrode of the transistor Tₙ₃₁ is configured to receive the voltage Vₙᵢ₁, and a drain electrode of the transistor Tₙ₃₁ is coupled to a node n₃₁. In one configuration, a source electrode of the transistor Tₙ₃₂ is coupled to the node n₃₁, a gate electrode of the transistor Tₙ₃₂ is coupled to a bias device (not shown for simplicity) to receive a bias voltage V_{bncas3}, and a drain electrode of the transistor Tₙ₃₂ is coupled to the node n₃₂. In one configuration, a source electrode of the transistor Tₙ₃₃ is coupled to the node n₃₂, a gate electrode of the transistor Tₙ₃₃ is coupled to a bias device (not shown for simplicity) to receive a bias voltage V_{bncas4}, and a drain electrode of the transistor Tₙ₃₃ is coupled to the node n₃₃. In this configuration, the transistors Tₙ₃₁, Tₙ₃₂, Tₙ₃₃ are connected to each other in series to form a cascode structure to amplify the voltage Vₙᵢ₁ to generate the output voltage Vₒᵤₜ₁ at the node n₃₃.

In one configuration, a source electrode of the transistor Tₚ₃₁ is coupled to the supply voltage rail to receive the first reference voltage (e.g., VDD or 1.2V), a gate electrode of the transistor Tₚ₃₁ is configured to receive the voltage Vₚᵢ₁, and a drain electrode of the transistor Tₚ₃₁ is coupled to a node n₃₅. In one configuration, a source electrode of the transistor Tₚ₃₂ is coupled to the node n₃₅, a gate electrode of the transistor Tₚ₃₂ is coupled to a bias device (not shown for simplicity) to receive a bias voltage V_{bpcas3}, and a drain electrode of the transistor Tₚ₃₂ is coupled to the node n₃₄. In one configuration, a source electrode of the transistor Tₚ₃₃ is coupled to the node n₃₄, a gate electrode of the transistor Tₚ₃₃ is coupled to a bias device (not shown for simplicity) to receive a bias voltage V_{bpcas4}, and a drain electrode of the transistor Tₚ₃₃ is coupled to the node n₃₃. In this configuration, the transistors Tₚ₃₁, Tₚ₃₂, Tₚ₃₃ are connected to each other in series to form a cascode structure to amplify the voltage Vₚᵢ₁ to generate the output voltage Vₒᵤₜ₁ at the node n₃₃. In one aspect, the transistors Tₚ₃₁, Tₚ₃₂, Tₚ₃₃ are configured and operate as a counter part of the transistors Tₙ₃₁, Tₙ₃₂, Tₙ₃₃.

In some embodiments, the transistors Tₙ₄₁, Tₙ₄₂, Tₙ₄₃, Tₚ₄₁, Tₚ₄₂, Tₚ₄₃ are configured and operate in a similar manner as the transistors Tₙ₃₁, Tₙ₃₂, Tₙ₃₃, Tₚ₃₁, Tₚ₃₂, Tₚ₃₃, such that the transistors Tₙ₃₁, Tₙ₃₂, Tₙ₃₃, Tₚ₃₁, Tₚ₃₂, Tₚ₃₃ operate as the half circuit, and the transistors Tₙ₄₁, Tₙ₄₂, Tₙ₄₃, Tₚ₄₁, Tₚ₄₂, Tₚ₄₃ operate as the other half circuit. In one aspect, the voltages Vₙᵢ₂, Vₚᵢ₂ are amplified by the transistors Tₙ₄₁, Tₙ₄₂, Tₙ₄₃, Tₚ₄₁, Tₚ₄₂, Tₚ₄₃ to generate the output voltage Vₒᵤₜ₂ at the node n₄₃. Thus, duplicated description thereof is omitted herein for the sake of brevity.

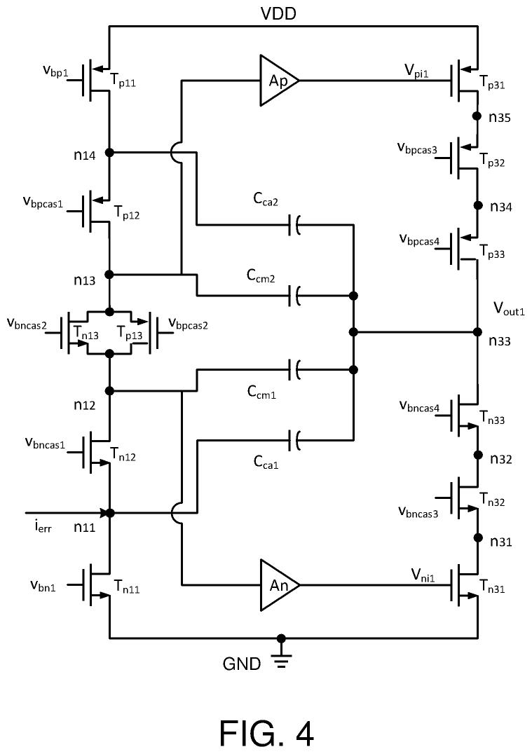

Referring to FIG. 4, illustrated is a diagram depicting a connection between the first stage amplifier 130 and the second stage amplifier 140. For simplicity, a connection between the half circuit of the first stage amplifier 130 and the half circuit of the second stage amplifier 140 is shown. In some embodiments, the half circuit of the first stage amplifier 130 is connected to the half circuit of the second stage 140 through amplifiers Ap, An, (also referred to as “buffer amplifiers” or “buffer amplifier circuits”) and capacitors C_{ca1}, C_{ca2}, C_{cm1}, C_{cm2}. In some embodiments, the connection between the first stage amplifier 130 and the second stage amplifier 140 enables a voltage or current from the first stage amplifier 130 to be amplified by the second stage amplifier 140. Moreover, the connection between the first stage amplifier 130 and the second stage amplifier 140 enables the output voltage Vₒᵤₜ₁ from the second stage amplifier 140 to be provided to the first stage amplifier 130 for feedback. In other embodiments, the connection between the first stage amplifier 130 and the second stage amplifier 140 includes more, fewer, or different components than shown in FIG. 4.

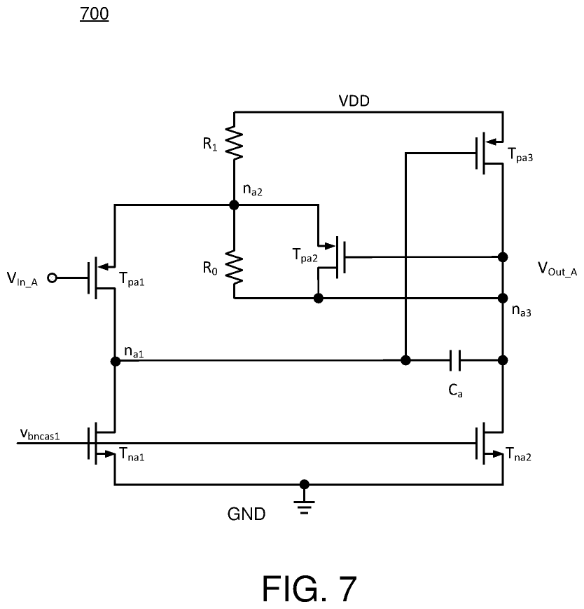

The amplifier Ap can be or correspond to a component that receives the voltage at the node n₁₃ of the first stage amplifier 140, and amplifies the voltage at the node n₁₃ to generate the voltage Vₚᵢ₁. In one configuration, the amplifier Ap is coupled between the node n₁₃ and the gate electrode of the transistor Tₚ₃₁. The amplifier Ap may be implemented or operate as a buffer or a level shifter to bias the transistor Tₚ₃₁. In this configuration, the amplifier Ap may amplify the voltage at the node n₁₃ according to an amplification gain of the amplifier Ap to generate the voltage Vₚᵢ₁. The amplification gain may be predetermined or adjustable. In one aspect, the amplification gain is adaptively adjusted according to the output voltage Vₒᵤₜ₁ or according to the load current through the output circuit (e.g., the second stage amplifier 140) to improve stability. Detailed description on the implementation and the operation of the amplifier Ap is provided below with respect to FIG. 7.

The amplifier An is a component that receives the voltage at the node n₁₂ of the first stage amplifier 140, and amplifies the voltage at the node n₁₂ to generate the voltage Vₙᵢ₁. In one configuration, the amplifier An is coupled between the node n₁₂ and the gate electrode of the transistor Tₙ₃₁. The amplifier An may be implemented or operate as a buffer or a level shifter to bias the transistor Tₙ₃₁. In this configuration, the amplifier An may amplify the voltage at the node n₁₂ according to an amplification gain of the amplifier An to generate the voltage Vₙᵢ₁. The amplification gain may be predetermined or adjustable. In one aspect, the amplification gain is adaptively adjusted according to the output voltage Vₒᵤₜ₁ or according to the load current through the output circuit (e.g., the second stage amplifier 140). The amplifier An may be implemented in a similar manner as the amplifier Ap with counterpart components (e.g., N-type transistors instead of P-type transistors or P-type transistors instead of N-type transistors).

The capacitors C_{ca1}, C_{ca2}, C_{cm1}, C_{cm2} can be or correspond to components for providing feedback from the second stage amplifier 140 to the first stage amplifier 130. In some embodiments, the capacitors C_{ca1}, C_{ca2}, C_{cm1}, C_{cm2} may be implemented as metal-insulator-metal capacitors, metal-oxide-metal capacitors or any capacitors. In one configuration, the capacitor C_{ca1} is coupled between the node n₁₁ and the node n₃₃, and the capacitor C_{cm1} is coupled between the node n₁₂ and the node n₃₃. Similarly, in one configuration, the capacitor C_{ca2} is coupled between the node n₁₄ and the node n₃₃, and the capacitor C_{cm2} is coupled between the node n₁₃ and the node n₃₃. In one aspect, the amplification gains of the amplifiers An and Ap may help improve the DC gain of the high-gain amplifier 120, but the amplifiers An and Ap may introduce or create poles that degrade the phase margin of the high-gain amplifier 120. In one aspect, the capacitors C_{ca1}, C_{ca2}, C_{cm1}, C_{cm2} allow feedback to improve phase margin of the high-gain amplifier 120, thereby improving the stability of the system 100.

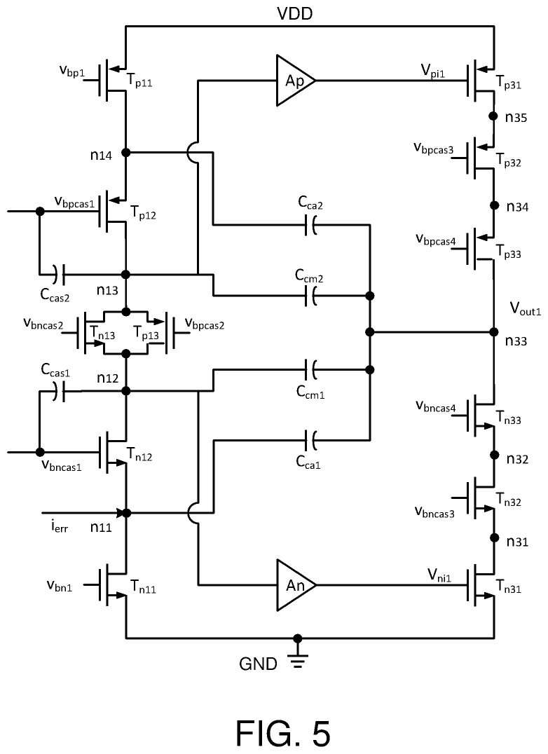

Referring to FIG. 5, illustrated is a diagram depicting an example arrangement including a connection between the first stage amplifier and the second stage amplifier with capacitors C_{cas1}, C_{cas2} disposed across the cascode transistors Tₙ₁₂, Tₚ₁₂ to improve stability. In one embodiment, the capacitor C_{cas1} is disposed across a gate electrode and a drain electrode of the cascode transistor Tₙ₁₂, and the capacitor C_{cas2} is disposed across a gate electrode and a drain electrode of the cascode transistor Tₚ₁₂. In this configuration, the capacitors C_{cas1}, C_{cas2} are implemented to improve stability of the system 100.

In one aspect, the high-gain amplifier 120 implementing the connection between the first stage amplifier 130 and the second stage amplifier 140 as shown in FIG. 4 is subject to trade-offs. In one example, the high gain amplifier 120 and the feedback amplifier 150 may form a first loop (referred to as “an outer loop”), and the first stage amplifier 130, the second stage amplifier 140 and a connection between them may form a second loop (referred to as “an inner loop”). To ensure a stable operation of the system 100, a UGB of the inner loop may be, for example, four or five times higher than a UGB of the outer loop. In one aspect, under no-load or low load current conditions, a transconductance of the output circuit (or the second stage amplifier 140) may be low, and the outer loop may suffer from a low phase margin. To ensure stability of the outer loop under no-load or low load current conditions, a transconductance of the output circuit (or the second stage amplifier 140) may be increased. However, when the load current supplied by the output circuit (or the second stage amplifier 140) increases either due to load demand from another circuit or due to a fast rising input (high slew rate and/or high load capacitor), the UGB of the inner loop may be increased compared to under a DC condition or when the load current is low, and the system 100 may become unstable. To ensure stability of the system 100 under high load current or high slew rate conditions, a transconductance of the output circuit (or the second stage amplifier 140) may be decreased.

Advantageously, the capacitors C_{cas1}, C_{cas2} across the cascode transistors Tₙ₁₂, Tₚ₁₂ may improve the stability of the system 100. In particular, the cascode structures of the first stage amplifier 130 and the second stage amplifier 140 may allow a high gain under no load or low current condition. Moreover, the capacitors C_{cas1}, C_{cas2} with the capacitors C_{ca1}, C_{ca2} may help improve the stability of the inner loop by pushing a non-dominant pole to a higher frequency under high current and/or high slew-rate conditions. Moreover, under large load current, the capacitors C_{cas1}, C_{cas2} with the capacitors C_{cm1}, C_{cm2} may help improve the stability of the inner loop by introducing a zero, under high current, and/or high slew-rate conditions. In one implementation, a capacitor may be added between the node n₁₂ and the ground voltage rail and another capacitor may be added between the node n₁₃ and the supply voltage rail to help improve stability. However, such implementation may not have an effect of improving the stability of the inner loop, for example, by pushing the non-dominant pole to a higher frequency according to the capacitors C_{cas1}, C_{cas2} as shown in FIG. 4, and may compromise UGB of the inner loop by pushing the dominant pole towards a DC or a lower frequency. Accordingly, the UGB of the system 100 and the stability of the system 100 may be improved, by increasing a transconductance of the output circuit (or the second stage amplifier 140) under no-load or low load current conditions, and by decreasing a transconductance of the output circuit (or the second stage amplifier 140) under high load current or high slew rate conditions.

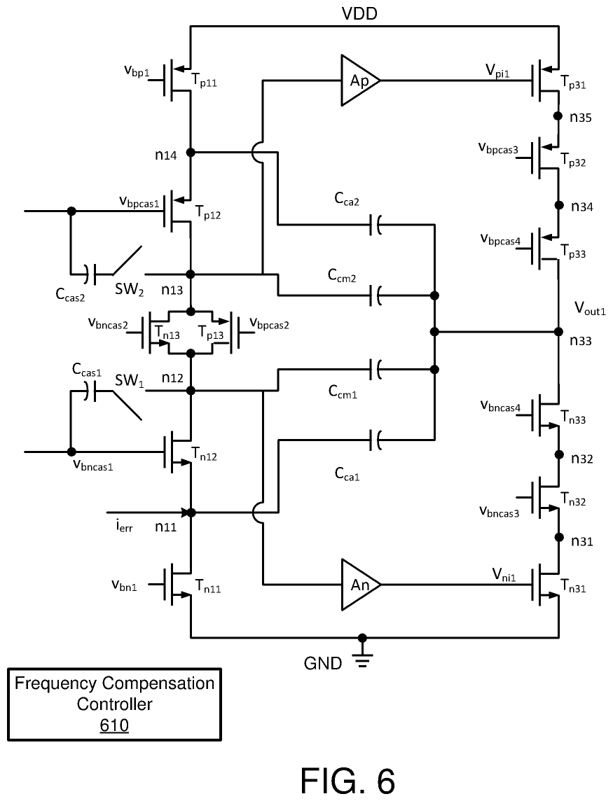

Referring to FIG. 6, illustrated is a diagram depicting an example arrangement including a connection between the first stage amplifier 130 and the second stage amplifier 140 with an adjustable frequency compensation. In some embodiments, a connection between the first stage amplifier 130 and the second stage amplifier 140 includes switches SW₁, SW₂ and the capacitors C_{cas1}, C_{cas2}, disposed across cascode transistors Tₙ₁₂, Tₚ₁₂. In some embodiments, the second stage amplifier 140 includes or is coupled to a frequency compensation controller 610. These components may operate together to enable or disable frequency compensation by the capacitors C_{cas1}, C_{cas2}, according to a load current through the output circuit or a slew rate.

In one aspect, the frequency compensation controller 610 may detect a load current through the second stage amplifier 140 (or the output circuit), and configure the switches SW₁, SW₂ to improve stability of the system 100. The frequency compensation controller 610 may detect current through the second stage amplifier 140 (or the output circuit) by implementing another current path mirroring the second stage amplifier 140, and detecting a current flow through the another current path. Alternatively, the frequency compensation controller 610 may detect a disturbance at one or more of the voltages V_{bncas3}, V_{bpcas3}, and detect a current through the second stage amplifier 140 according to the detected disturbance. In response to the frequency compensation controller 610 detecting a low load current less than a predetermined threshold through the second stage amplifier 140 (or in response to detecting a low slew rate), the frequency compensation controller 610 may disable the switches SW₁, SW₂ such that an electrode of the capacitor C_{cas1} is electrically decoupled from the cascode transistor Tₙ₁₂ and an electrode of the capacitor C_{cas2} is electrically decoupled from the cascode transistor Tₚ₁₂. In response to the frequency compensation controller 610 detecting a high load current over a predetermined threshold through the second stage amplifier 140 (or in response to detecting a high slew rate), the frequency compensation controller 610 may enable the switches SW₁, SW₂ such that the capacitor C_{cas1} is electrically coupled across the cascode transistor Tₙ₁₂ and the capacitor C_{cas2} is electrically coupled across the cascode transistor Tₚ₁₂. Accordingly, the UGB of the system 100 and the stability of the system 100 may be improved, by increasing a transconductance of the output circuit (or the second stage amplifier 140) under low load current or low slew rate conditions, and by decreasing a transconductance of the output circuit (or the second stage amplifier 140) under a high load current or high slew rate conditions.

Referring to FIG. 7, illustrated is a diagram depicting an amplifier 700 between the first stage amplifier and the second stage amplifier. In one aspect, the amplifier 700 may be implemented as the amplifier Ap or An of FIG. 5. In some embodiments, the amplifier 700 includes transistors Tₚₐ₁, Tₚₐ₂, Tₚₐ₃, Tₙₐ₁, Tₙₐ₂, resistors R₀, R₁, and a capacitor Cₐ. In some embodiments, the transistors Tₚₐ₁, Tₚₐ₂, Tₚₐ₃ are P-type transistors, and the Tₙₐ₁, Tₙₐ₂ are N-type transistors. The resistors R₀, R₁ may be implemented as active components or passive components. These components may operate together to receive the input voltage V_{In A} and amplify the input voltage V_{In_A} to generate an output voltage V_{Out_A} by an adjustable gain inversely proportional to a load current through the second stage amplifier 140. In other embodiments, the amplifier 700 includes more, fewer, or different components than shown in FIG. 7.

In one configuration, the resistor R₁ includes a first electrode coupled to the supply voltage rail to receive the first reference voltage (e.g., VDD or 1.2V) and a second electrode coupled to a node nₐ₂. In one configuration, the transistor Tₚₐ₁ includes a source electrode coupled to the node nₐ₂, a gate electrode to receive the input voltage V_{In_A}, and a drain electrode coupled to a node nₐ₁. In one configuration, the transistor Tₚₐ₂ includes a source electrode coupled to the node nₐ₂, a gate electrode coupled to a node nₐ₃, and a drain electrode coupled to the node nₐ₃ to form a diode-connected configuration. In one configuration, the resistor R₀ includes a first electrode coupled to the node nₐ₂ and a second electrode coupled to the node nₐ₃. In one configuration, the transistor Tₚₐ₃ includes a source electrode coupled to the supply voltage rail to receive the first reference voltage (e.g., VDD or 1.2V), a gate electrode coupled to the node nₐ₁, and a drain electrode coupled to the node nₐ₃. In one configuration, the capacitor Cₐ is coupled between the node nₐ₁ and the node nₐ₃. In one configuration, the transistor Tₙₐ₁ includes a source electrode coupled to the ground voltage rail to receive the second reference voltage (e.g., GND or 0V), a gate electrode to receive the bias voltage V_{bncas1}, and a drain electrode coupled to the node nₐ₁. In one configuration, the transistor Tₙₐ₂ includes a source electrode coupled to the ground voltage rail to receive the second reference voltage (e.g., GND or 0V), a gate electrode to receive the bias voltage V_{bncas1}, and a drain electrode coupled to the node nₐ₃.

In this configuration, a voltage gain of the amplifier 700 is adaptively adjusted according to a load current through the output circuit (or the second stage amplifier). The transistor Tₚₐ₁ may sense the input voltage V_{In_A} (e.g., a voltage at the node n13 of FIGS. 4, 5 and 6), and steer current from the resistor R₁, according to the sensed voltage. In one aspect, the load current through the output circuit (or the second stage amplifier) can be sensed by detecting the voltage V_{Out_A} at the node nₐ₃, and the gain of the amplifier 700 can be adjusted according to the detected voltage at the node nₐ₃. In one aspect, a lower voltage V_{Out_A} corresponds to a higher load current through the output circuit (or the second stage amplifier), and a higher voltage V_{Out_A} corresponds to a lower load current through the output circuit (or the second stage amplifier). In response to the voltage V_{Out_A} being lower than a predetermined voltage (e.g., VDD-threshold voltage of Tₚₐ₂), the transistor Tₚₐ₂ may be turned on and short the resistor R₀ to reduce the gain of the amplifier 700. In response to the voltage V_{Out_A} being higher than the predetermined voltage (e.g., VDD-threshold voltage of Tₚₐ₂), the transistor Tₚₐ₂ may be turned off to increase the gain of the amplifier 700. Accordingly, the UGB of the system 100 and the stability of the system 100 may be improved, by increasing a gain of the amplifier 700 under low load current or low slew rate conditions, and by decreasing a gain of the amplifier 700 under a high load current or high slew rate conditions.

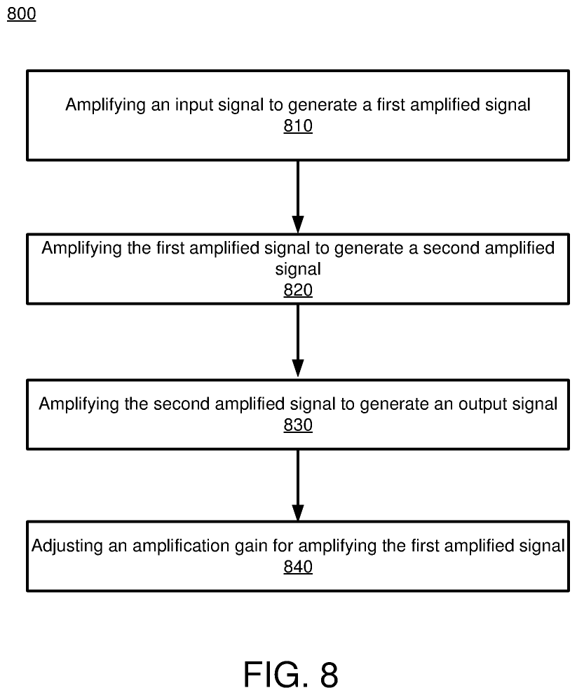

Referring to FIG. 8, illustrated is a flow chart depicting an example operation 800 of adjusting an amplifier gain for improving stability. In some embodiments, the operation 800 is performed by the system 100 of FIG. 1. In some embodiments, the operation 800 is performed by other entities. In some embodiments, the operation 800 includes more, fewer, or different steps than shown in FIG. 8.

In one approach, the system 100 amplifies 810 an input signal to generate a first amplified signal. In one aspect, the first stage amplifier 130 may include a first transistor (e.g., Tₙ₁₁) and a second transistor (Tₙ₁₂) coupled to each other in series in a cascode structure, where the second transistor operates as a cascode transistor. In one approach, a current corresponding to the input signal may be injected to a node between the first transistor and the second transistor, and converted into a voltage by a high output impedance at the cascode transistor to amplify the input signal.

In one approach, the system 100 amplifies 820 the first amplified signal to generate a second amplified signal by amplifying the first amplified signal. In one implementation, an additional amplifier (e.g., amplifier Ap or amplifier An) may be implemented between the first stage amplifier 130 and the second stage amplifier 140 to increase the gain further. In one aspect, the additional amplifier may have an adjustable gain. The additional amplifier may amplify the first amplified signal according to a predetermined gain to generate the second amplified signal. In one approach, the system 100 amplifies 830 the second amplified signal to generate an output signal. In one approach, the second stage amplifier 140 may include transistors having a cascode structure to amplify the second amplified signal with a high gain to generate the output signal.

In one approach, the system 100 adjusts 840 an amplification gain for amplifying the first amplified signal, for example, according to a load current through the output circuit (or the second stage amplifier). The additional amplifier may detect the load current by sensing a voltage at an output of the additional amplifier or at an input of the output circuit. The additional amplifier may reduce the gain of the additional amplifier, in response to detecting the load current exceeding a predetermined threshold. The additional amplifier may increase the gain of the additional amplifier, in response to detecting the load current not exceeding the predetermined threshold. Accordingly, the UGB of the system 100 and the stability of the system 100 may be improved, by increasing a gain of the additional amplifier under low load current or low slew rate conditions, and by decreasing a gain of the additional amplifier under a high load current or high slew rate conditions.

### B. Computing and Network Environment

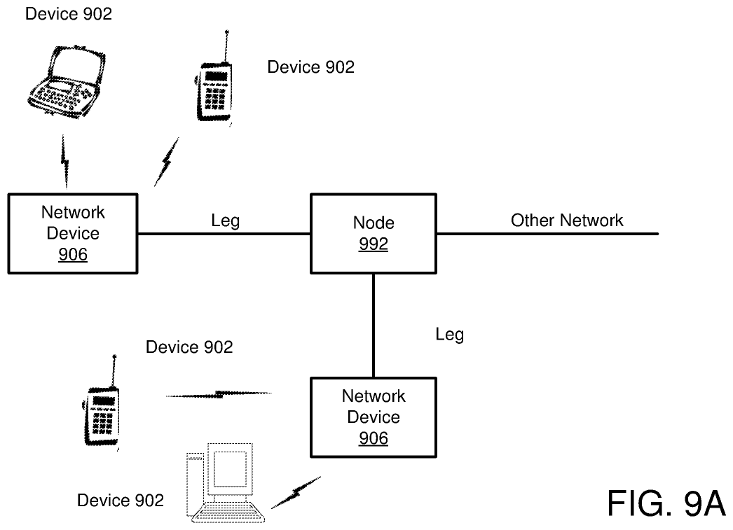

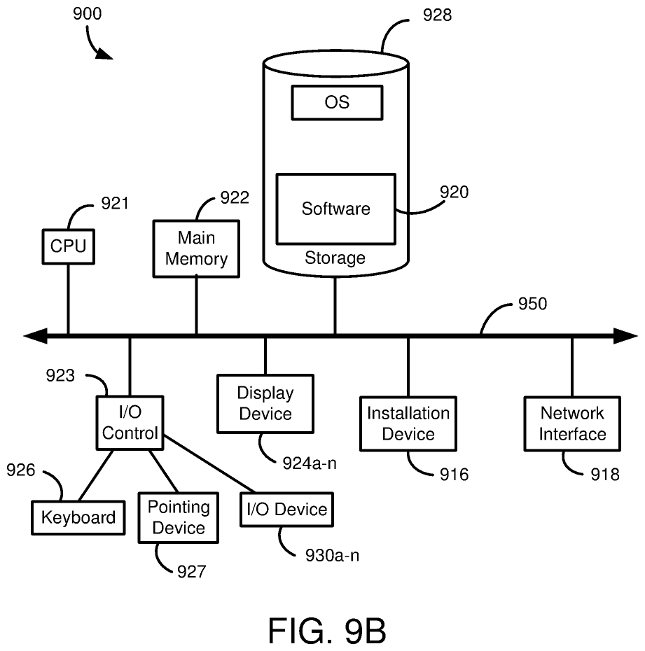

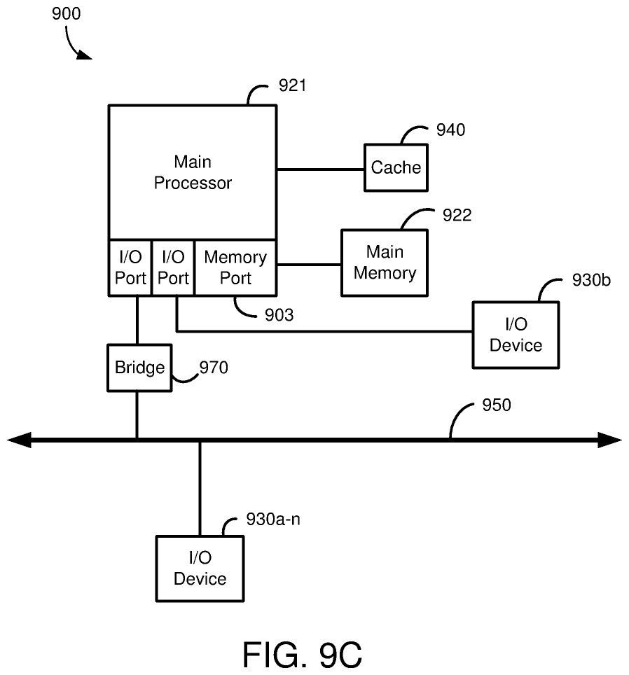

Having discussed specific embodiments of the present solution, it may be helpful to describe aspects of the operating environment as well as associated system components (e.g., hardware elements) in connection with the methods and systems described herein. Referring to FIG. 9A, an embodiment of a network environment is depicted. In brief overview, the network environment includes a communication system that includes one or more network devices 906, one or more communication devices 902 and a node 992. The communication devices 902 may for example include laptop computers 902, tablets 902, personal computers 902 and/or cellular telephone devices 902. In some embodiments, the device 902, the network device 906, the node 992, or any combination is implemented as a device employing the system 100 of FIG. 1. The details of an embodiment of each communication device and/or network device are described in greater detail with reference to FIGS. 9B and 9C. The network environment can be an ad hoc network environment, an infrastructure network environment, a subnet environment, etc.

The network devices 906 may be operably coupled to the node 992 via local area network connections. The node 992, which may include a router, gateway, switch, bridge, modem, system controller, appliance, etc., may provide a local area network connection for the communication system. Each of the network devices 906 may have an associated antenna or an antenna array to communicate with the communication devices 902 in its area. The communication devices 902 may register with a particular network device 906 to receive services from the communication system (e.g., via a SU-MIMO or MU-MIMO configuration). For direct connections (e.g., point-to-point communications), some communication devices 902 may communicate directly via an allocated channel and communications protocol. Some of the communication devices 902 may be mobile or relatively static with respect to the network device 906.

In some embodiments a network device 906 includes a device or module (including a combination of hardware and software) that allows communication devices 902 to connect to a wired network using Wi-Fi, or other standards. A network device 906 may be configured, designed, and/or built for operating in a wireless local area network (WLAN). A network device 906 may connect to a router (e.g., via a wired network) as a standalone device in some embodiments. In other embodiments, a network device can be a component of a router. A network device 906 can provide multiple devices 902 access to a network. A network device 906 may, for example, connect to the devices 902 through a wired Ethernet connection, a wireless Wi-Fi connection, or both. A network device 906 may be built and/or configured to support a standard for sending and receiving data using one or more radio frequencies. Those standards, and the frequencies they use may be defined by the IEEE (e.g., IEEE 802.11 standards). A network device may be configured and/or used to support public Internet hotspots, and/or on an internal network to extend the network's Wi-Fi signal range.

In some embodiments, the network devices 906 may be used for (e.g., in-home or in-building) wireless networks (e.g., IEEE 802.11, Bluetooth, ZigBee, any other type of radio frequency based network protocol and/or variations thereof). Each of the communication devices 902 may include a built-in radio and/or is coupled to a radio. Such communication devices 902 and/or network devices 906 may operate in accordance with the various aspects of the disclosure as presented herein to enhance performance, reduce costs and/or size, and/or enhance broadband applications. Each communication devices 902 may have the capacity to function as a client node seeking access to resources (e.g., data, and connection to networked nodes such as servers) via one or more network devices 906.

The network connections may include any type and/or form of network and may include any of the following: a point-to-point network, a broadcast network, a telecommunications network, a data communication network, and a computer network. The topology of the network may be a bus, star, or ring network topology. The network may be of any such network topology as known to those ordinarily skilled in the art capable of supporting the operations described herein. In some embodiments, different types of data may be transmitted via different protocols. In other embodiments, the same types of data may be transmitted via different protocols.

The node 992, the communications device(s) 902 and network device(s) 906 may be deployed as and/or executed on any type and form of computing device, such as a computer, network device or appliance capable of communicating on any type and form of network and performing the operations described herein. FIGS. 9B and 9C depict block diagrams of a computing device 900 useful for practicing an embodiment of the node 992, the communication devices 902 or the network device 906. As shown in FIGS. 9B and 9C, each computing device 900 includes a central processing unit 921, and a main memory unit 922. As shown in FIG. 9B, a computing device 900 may include a storage device 928, an installation device 916, a network interface 918, an I/O controller 923, display devices 924a-924n, a keyboard 926 and a pointing device 927, such as a mouse. The storage device 928 may include, without limitation, an operating system and/or software. As shown in FIG. 9C, each computing device 900 may also include additional optional elements, such as a memory port 903, a bridge 970, one or more input/output devices 930a-930n (generally referred to using reference numeral 930), and a cache memory 940 in communication with the central processing unit 921.

The central processing unit 921 is any logic circuitry that responds to and processes instructions fetched from the main memory unit 922. In many embodiments, the central processing unit 921 is provided by a microprocessor unit, such as: those manufactured by Intel Corporation of Santa Clara, Calif.; those manufactured by International Business Machines of White Plains, N.Y.; or those manufactured by Advanced Micro Devices of Sunnyvale, Calif. The computing device 900 may be based on any of these processors, or any other processor capable of operating as described herein.

Main memory unit 922 may be one or more memory chips capable of storing data and allowing any storage location to be directly accessed by the microprocessor 921, such as any type or variant of Static random access memory (SRAM), Dynamic random access memory (DRAM), Ferroelectric RAM (FRAM), NAND Flash, NOR Flash and Solid State Drives (SSD). The main memory 922 may be based on any of the above described memory chips, or any other available memory chips capable of operating as described herein. In the embodiment shown in FIG. 9B, the processor 921 communicates with main memory 922 via a system bus 950 (described in more detail below). FIG. 9C depicts an embodiment of a computing device 900 in which the processor communicates directly with main memory 922 via a memory port 903. For example, in FIG. 9C the main memory 922 may be DRDRAM.

FIG. 9C depicts an embodiment in which the main processor 921 communicates directly with cache memory 940 via a secondary bus, sometimes referred to as a backside bus. In other embodiments, the main processor 921 communicates with cache memory 940 using the system bus 950. Cache memory 940 typically has a faster response time than main memory 922 and is provided by, for example, SRAM, BSRAM, or EDRAM. In the embodiment shown in FIG. 9C, the processor 921 communicates with various I/O devices 930 via a local system bus 950. Various buses may be used to connect the central processing unit 921 to any of the I/O devices 930, for example, a VESA VL bus, an ISA bus, an EISA bus, a MicroChannel Architecture (MCA) bus, a PCI bus, a PCI-X bus, a PCI-Express bus, or a NuBus. For embodiments in which the I/O device is a video display 924, the processor 921 may use an Advanced Graphics Port (AGP) to communicate with the display 924. FIG. 9C depicts an embodiment of a computer 900 in which the main processor 921 may communicate directly with I/O device 930b, for example via HYPERTRANSPORT, RAPIDIO, or INFINIBAND communications technology. FIG. 9C also depicts an embodiment in which local busses and direct communication are mixed: the processor 921 communicates with I/O device 930a using a local interconnect bus while communicating with I/O device 930b directly.

A wide variety of I/O devices 930a-930n may be present in the computing device 900. Input devices include keyboards, mice, trackpads, trackballs, microphones, dials, touch pads, touch screen, and drawing tablets. Output devices include video displays, speakers, inkjet printers, laser printers, projectors, and dye-sublimation printers. The I/O devices may be controlled by an I/O controller 923 as shown in FIG. 9B. The I/O controller may control one or more I/O devices such as a keyboard 926 and a pointing device 927, e.g., a mouse or optical pen. Furthermore, an I/O device may also provide storage and/or an installation medium 916 for the computing device 900. In still other embodiments, the computing device 900 may provide USB connections (not shown) to receive handheld USB storage devices such as the USB Flash Drive line of devices manufactured by Twintech Industry, Inc. of Los Alamitos, Calif.

Referring again to FIG. 9B, the computing device 900 may support any suitable installation device 916, such as a disk drive, a CD-ROM drive, a CD-R/RW drive, a DVD-ROM drive, a flash memory drive, tape drives of various formats, USB device, hard-drive, a network interface, or any other device suitable for installing software and programs. The computing device 900 may further include a storage device, such as one or more hard disk drives or redundant arrays of independent disks, for storing an operating system and other related software, and for storing application software programs such as any program or software 920 for implementing (e.g., configured and/or designed for) the systems and methods described herein. Optionally, any of the installation devices 916 could also be used as the storage device. Additionally, the operating system and the software can be run from a bootable medium.

Furthermore, the computing device 900 may include a network interface 918 to interface to the network 904 through a variety of connections including, but not limited to, standard telephone lines, LAN or WAN links (e.g., 802.11, T1, T3, 56 kb, X.25, SNA, DECNET), broadband connections (e.g., ISDN, Frame Relay, ATM, Gigabit Ethernet, Ethernet-over-SONET), wireless connections, or some combination of any or all of the above. Connections can be established using a variety of communication protocols (e.g., TCP/IP, IPX, SPX, NetBIOS, Ethernet, ARCNET, SONET, SDH, Fiber Distributed Data Interface (FDDI), RS232, IEEE 802.11, IEEE 802.11a, IEEE 802.11b, IEEE 802.11g, IEEE 802.11n, IEEE 802.11ac, IEEE 802.11ad, CDMA, GSM, WiMax and direct asynchronous connections). In one embodiment, the computing device 900 communicates with other computing devices 900′ via any type and/or form of gateway or tunneling protocol such as Secure Socket Layer (SSL) or Transport Layer Security (TLS). The network interface 918 may include a built-in network adapter, network interface card, PCMCIA network card, card bus network adapter, wireless network adapter, USB network adapter, modem or any other device suitable for interfacing the computing device 900 to any type of network capable of communication and performing the operations described herein.

In some embodiments, the computing device 900 may include or be connected to one or more display devices 924a-924n. As such, any of the I/O devices 930a-930n and/or the I/O controller 923 may include any type and/or form of suitable hardware, software, or combination of hardware and software to support, enable or provide for the connection and use of the display device(s) 924a-924n by the computing device 900. For example, the computing device 900 may include any type and/or form of video adapter, video card, driver, and/or library to interface, communicate, connect or otherwise use the display device(s) 924a-924n. In one embodiment, a video adapter may include multiple connectors to interface to the display device(s) 924a-924n. In other embodiments, the computing device 900 may include multiple video adapters, with each video adapter connected to the display device(s) 924a-924n. In some embodiments, any portion of the operating system of the computing device 900 may be configured for using multiple displays 924a-924n. One ordinarily skilled in the art will recognize and appreciate the various ways and embodiments that a computing device 900 may be configured to have one or more display devices 924a-924n.

In further embodiments, an I/O device 930 may be a bridge between the system bus 950 and an external communication bus, such as a USB bus, an Apple Desktop Bus, an RS-232 serial connection, a SCSI bus, a FireWire bus, a FireWire 900 bus, an Ethernet bus, an AppleTalk bus, a Gigabit Ethernet bus, an Asynchronous Transfer Mode bus, a FibreChannel bus, a Serial Attached small computer system interface bus, a USB connection, or a HDMI bus.

A computing device 900 of the sort depicted in FIGS. 9B and 9C may operate under the control of an operating system, which control scheduling of tasks and access to system resources. The computing device 900 can be running any operating system such as any of the versions of the MICROSOFT WINDOWS operating systems, the different releases of the Unix and Linux operating systems, any version of the MAC OS for Macintosh computers, any embedded operating system, any real-time operating system, any open source operating system, any proprietary operating system, any operating systems for mobile computing devices, or any other operating system capable of running on the computing device and performing the operations described herein. Typical operating systems include, but are not limited to: Android, produced by Google Inc.; WINDOWS 7 and 8, produced by Microsoft Corporation of Redmond, Wash.; MAC OS, produced by Apple Computer of Cupertino, Calif.; WebOS, produced by Research In Motion (RIMI); OS/2, produced by International Business Machines of Armonk, N.Y.; and Linux, a freely-available operating system distributed by Caldera Corp. of Salt Lake City, Utah, or any type and/or form of a Unix operating system, among others.

The computer system 900 can be any workstation, telephone, desktop computer, laptop or notebook computer, server, handheld computer, mobile telephone or other portable telecommunications device, media playing device, a gaming system, mobile computing device, or any other type and/or form of computing, telecommunications or media device that is capable of communication. The computer system 900 has sufficient processor power and memory capacity to perform the operations described herein.

In some embodiments, the computing device 900 may have different processors, operating systems, and input devices consistent with the device. For example, in one embodiment, the computing device 900 is a smart phone, mobile device, tablet or personal digital assistant. In still other embodiments, the computing device 900 is an Android-based mobile device, an iPhone smart phone manufactured by Apple Computer of Cupertino, Calif., or a Blackberry or WebOS-based handheld device or smart phone, such as the devices manufactured by Research In Motion Limited. Moreover, the computing device 900 can be any workstation, desktop computer, laptop or notebook computer, server, handheld computer, mobile telephone, any other computer, or other form of computing or telecommunications device that is capable of communication and that has sufficient processor power and memory capacity to perform the operations described herein.

Although the disclosure may reference one or more “users”, such “users” may refer to user-associated devices, for example, consistent with the terms “user” and “multi-user” typically used in the context of a multi-user multiple-input and multiple-output (MU-MIMO) environment.

Although examples of communications systems described above may include devices and network devices operating according to PAM4 DFE protocol, it should be understood that embodiments of the systems and methods described can operate according to other standards.

It should be noted that certain passages of this disclosure may reference terms such as “first” and “second” in connection with devices, mode of operation, transmit chains, antennas, etc., for purposes of identifying or differentiating one from another or from others. These terms are not intended to merely relate entities (e.g., a first device and a second device) temporally or according to a sequence, although in some cases, these entities may include such a relationship. Nor do these terms limit the number of possible entities (e.g., devices) that may operate within a system or environment.

It should be understood that the systems described above may provide multiple ones of any or each of those components and these components may be provided on either a standalone machine or, in some embodiments, on multiple machines in a distributed system. In addition, the systems and methods described above may be provided as one or more computer-readable programs or executable instructions embodied on or in one or more articles of manufacture. The article of manufacture may be a floppy disk, a hard disk, a CD-ROM, a flash memory card, a PROM, a RAM, a ROM, or a magnetic tape. In general, the computer-readable programs may be implemented in any programming language, such as LISP, PERL, C, C++, C #, PROLOG, or in any byte code language such as JAVA. The software programs or executable instructions may be stored on or in one or more articles of manufacture as object code.

While the foregoing written description of the methods and systems enables one of ordinary skill to make and use what is considered presently to be the best mode thereof, those of ordinary skill will understand and appreciate the existence of variations, combinations, and equivalents of the specific embodiment, method, and examples herein. The present methods and systems should therefore not be limited by the above described embodiments, methods, and examples, but by all embodiments and methods within the scope and spirit of the disclosure.

We claim:

1. An apparatus comprising:
an input sensing circuit to generate an input signal;
a cascode circuit coupled to the input sensing circuit, the cascode circuit including a first transistor and a second transistor coupled to each other in series, the cascode circuit to generate a first amplified signal by amplifying the input signal from the input sensing circuit;
an amplifier circuit coupled to an output of the cascode circuit, the amplifier circuit to generate a second amplified signal by amplifying the first amplified signal;
an output circuit coupled to an output of the amplifier circuit, the output circuit to generate an output signal by amplifying the second amplified signal;
a first capacitor disposed across the second transistor; and
a second capacitor coupled between the output circuit and the cascode circuit.

2. The apparatus of claim 1, wherein the first capacitor is coupled between a first electrode of the second transistor and a second electrode of the second transistor.

3. The apparatus of claim 2, wherein the second capacitor is coupled between an output of the output circuit and the second electrode of the second transistor.

4. The apparatus of claim 3, wherein the second electrode of the second transistor is the output of the cascode circuit.

5. The apparatus of claim 3, further comprising a third capacitor coupled between the output of the output circuit and a third electrode of the second transistor.

6. The apparatus of claim 5, wherein the input sensing circuit is directly coupled to the third electrode of the second transistor.

7. The apparatus of claim 5, wherein the cascode circuit further includes:
a pair of buffer transistors,
a third transistor, and
a fourth transistor, wherein the first transistor, the second transistor, the pair of buffer transistors, the third transistor, and the fourth transistor are coupled to each other in series.

8. The apparatus of claim 7, wherein the first transistor and the second transistor are N-type transistors, and wherein the third transistor and the fourth transistor are P-type transistors.

9. The apparatus of claim 7, wherein the pair of buffer transistors include an N-type transistor and a P-type transistor coupled to each other in parallel.

10. The apparatus of claim 7, further comprising:
a fourth capacitor coupled between a first electrode and a second electrode of the fourth transistor;
a fifth capacitor coupled between the second electrode of the fourth transistor and the output of the output circuit; and
a sixth capacitor coupled between a third electrode of the fourth transistor and the output of the output circuit.

11. The apparatus of claim 10, further comprising:
another amplifier circuit coupled between the second electrode of the fourth transistor and another input of the output circuit.

12. The apparatus of claim 1, wherein the input sensing circuit and the cascode circuit form a folded cascode amplifier.

13. The apparatus of claim 1, further comprising:
a switch coupled to the first capacitor in series across the second transistor; and
a frequency compensation controller coupled to the output circuit, the frequency compensation controller to sense load current through the output circuit and enable or disable the switch according to the load current.

14. The apparatus of claim 1, wherein the amplifier circuit is configured to:
adjust an amplification gain for amplifying the first amplified signal according to a voltage at the output of the output circuit.

15. The apparatus of claim 14, wherein the amplifier circuit includes:
an input transistor including a gate electrode coupled to the output of the cascode circuit,
a diode connected transistor including:
a source electrode coupled to a source electrode of the input transistor, and
a drain electrode coupled to a gate electrode of the diode connected transistor, the drain electrode of the diode connected transistor coupled to an input of the output circuit, and
a resistor coupled between the source electrode of the diode connected transistor and the drain electrode of the diode connected transistor.

16. An apparatus comprising:
a cascode circuit including a first transistor and a second transistor coupled to each other in series, the cascode circuit to generate a first amplified signal by amplifying an input signal;
an amplifier circuit coupled to an output of the cascode circuit, the amplifier circuit to generate a second amplified signal by amplifying the first amplified signal;
an output circuit coupled to an output of the amplifier circuit, the output circuit to generate an output signal by amplifying the second amplified signal;
a first capacitor and a switch coupled to each other in series between a gate electrode of the second transistor and a drain electrode of the second transistor; and
a second capacitor coupled between an output of the output circuit and the drain electrode of the second transistor.

17. The apparatus of claim 16, further comprising:
a frequency compensation controller coupled to the output circuit, the frequency compensation controller to sense load current through the output circuit and enable or disable the switch according to the load current.

18. The apparatus of claim 17, further comprising:
a third capacitor coupled between the output of the output circuit and a source electrode of the second transistor.

19. The apparatus of claim 16, wherein the amplifier circuit is configured to:
adjust an amplification gain for amplifying the first amplified signal according to a voltage at the output of the output circuit.

20. A method comprising:
amplifying, by a cascode circuit including a first transistor and a second transistor coupled to each other in series, an input signal to generate a first amplified signal;
amplifying, by an amplifier circuit coupled to an output of the cascode circuit, the first amplified signal to generate a second amplified signal;
amplifying, by an output circuit coupled to an output of the amplifier circuit, the second amplified signal to generate an output signal; and
adjusting, by the amplifier circuit, an amplification gain for amplifying the first amplified signal according to a current through the output circuit.
